(19) United States
(12) Patent Application Publication
(10) Pub. No.: US 2025/0255195 A1
(43) Pub. Date: Aug. 7, 2025

(54) Buffer Layers to Grow BiSb and YPtBi to Match the Crystal Symmetry of Interlayers and Ferromagnetic layers to Generate Spin-Polarized Current

(71) Applicant: Western Digital Technologies, Inc., San Jose, CA (US)

(72) Inventors: Quang LE, San Jose, CA (US); Brian R. YORK, San Jose, CA (US); Michael A. GRIBELYUK, Stamford, CT (US); Xiaoyong LIU, San Jose, CA (US); Son T. LE, San Jose, CA (US); Maki MAEDA, Fujisawa-shi (JP); Hisashi TAKANO, Fujisawa-shi (JP)

(73) Assignee: Western Digital Technologies, Inc., San Jose, CA (US)

(21) Appl. No.: 19/041,211

(22) Filed: Jan. 30, 2025

Related U.S. Application Data
(60) Provisional application No. 63/627,924, filed on Feb. 1, 2024.

(51) Int. Cl. H10N 50/85; G11B 5/00; G11B 5/39; G11C 11/16; H10N 50/10

(52) U.S. Cl. CPC H10N 50/85; G11B 5/3909; G11C 11/161; H10N 50/10; G11B 2005/0024

(57) ABSTRACT

The present disclosure generally relates to topological material based spin-orbit torque (SOT) devices. The SOT device comprises a seed layer, a texture layer disposed on the seed layer, a first barrier layer disposed on the texture layer, a ferromagnetic (FM) layer disposed over the first barrier layer, a topological insulator (TI) or topological semi-metal (TSM) layer disposed over the first barrier layer, the TI or TSM layer comprising YPtBi or BiSb, and a second barrier layer disposed between the FM layer and the TI or TSM layer. In one embodiment, the texture layer, the first and second barrier layers, and the FM layer have a (100) orientation, and the TI or TSM layer comprises (012) BiSb or (100) YPtBi. In another embodiment, the texture layer, the first and second barrier layers, and the FM layer have a (110) orientation, and the TI or TSM layer comprises (110) YPtBi.

### CROSS-REFERENCE TO RELATED APPLICATIONS

This application claims benefit of U.S. provisional patent application Ser. No. 63/627,924, filed Feb. 1, 2024, which is herein incorporated by reference.

### BACKGROUND OF THE DISCLOSURE

### Field of the Disclosure

Embodiments of the present disclosure generally relate to spin-orbit torque (SOT) devices comprising a topological material layer.

### Description of the Related Art

BiSb layers are narrow band gap topological insulators with both giant spin Hall effect and high electrical conductivity. BiSb is a material that has been proposed in various spin-orbit torque (SOT) device applications, such as for a spin Hall layer for magnetoresistive random access memory (MRAM) devices, magnetic recording read heads, sensors, and energy-assisted magnetic recording (EAMR) magnetic recording heads.

However, utilizing BiSb materials in commercial SOT applications can present several obstacles. For example, BiSb materials have low melting points, large grain sizes, significant Sb migration issues upon thermal annealing due to its film roughness, difficulty maintaining a desired (012), (001), or (11) orientation for maximum spin Hall effect, and are generally soft and easily damaged by ion milling.

Therefore, there is a need for an improved SOT device utilizing a topological insulator (TI) or topological semi-metal (TSM) layer having a desired crystal orientation.

### SUMMARY OF THE DISCLOSURE

The present disclosure generally relates to topological material based spin-orbit torque (SOT) devices. The SOT device comprises a seed layer, a texture layer disposed on the seed layer, a first barrier layer disposed on the texture layer, a ferromagnetic (FM) layer disposed over the first barrier layer, a topological insulator (TI) or topological semi-metal (TSM) layer disposed over the first barrier layer, the TI or TSM layer comprising YPtBi or BiSb, and a second barrier layer disposed between the FM layer and the TI or TSM layer. In one embodiment, the texture layer, the first and second barrier layers, and the FM layer have a (100) orientation, and the TI or TSM layer comprises (012) BiSb or (100) YPtBi. In another embodiment, the texture layer, the first and second barrier layers, and the FM layer have a (110) orientation, and the TI or TSM layer comprises (110) YPtBi.

In one embodiment, a spin-orbit torque (SOT) device comprises a seed layer, a (100) texture layer disposed on the seed layer, a first (100) barrier layer disposed on the (100) texture layer, a (100) ferromagnetic (FM) layer disposed over the first (100) barrier layer, a topological insulator (TI) or topological semi-metal (TSM) layer disposed over the first (100) barrier layer, the TI or TSM layer comprising YPtBi in a (100) orientation or BiSb in a (012) orientation, and a second (100) barrier layer disposed between the (100) FM layer and the TI or TSM layer.

In another embodiment, a spin-orbit torque (SOT) device comprises a seed layer, a (110) texture layer disposed on the seed layer, a first (110) barrier layer disposed on the (110) texture layer, a (110) ferromagnetic (FM) layer disposed over the first (110) barrier layer, a topological semi-metal (TSM) layer disposed over the first (110) barrier layer, the TSM layer comprising YPtBi in a (110) orientation, and a second (110) barrier layer disposed between the (110) FM layer and the TSM layer.

In yet another embodiment, a spin-orbit torque (SOT) device comprises a seed layer, a (100) texture layer disposed on the seed layer, a first (100) barrier layer disposed on the (100) texture layer, a (100) ferromagnetic (FM) layer disposed over the first (100) barrier layer, a topological semi-metal (TSM) layer disposed over the first (100) barrier layer, the TSM layer comprising YPtBi in a (100) orientation, and a second (100) barrier layer disposed between the (100) FM layer and the TSM layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic illustration of certain embodiments of a magnetic media drive including a magnetic recording head having a SOT MTJ device.

FIG. 2 is a fragmented, cross-sectional side view of certain embodiments of a read/write head having a SOT MTJ device.

FIGS. 3A-3D illustrate spin orbit torque (SOT) devices, according to various embodiments.

FIG. 4 illustrates a graph showing examples of texture layers which could be used to produce a YPtBi (100) texture and/or a BiSb (012) texture, according to one embodiment.

FIG. 5A is a schematic cross-sectional view of a SOT device for use in a MAMR magnetic recording head, such as the MAMR magnetic recording head of the drive of FIG. 1 or other suitable magnetic media drives.

FIGS. 5B-5C are schematic MFS views of certain embodiments of a portion of a MAMR magnetic recording head with a SOT device of FIG. 5A.

FIG. 6 is a schematic cross-sectional view of an MRAM device according to one embodiment, which has a top SOT stack configuration.

FIG. 7 is a schematic cross-sectional view of another MRAM device according to one embodiment, which has a bottom SOT stack configuration, with a TI or TSM bottom layer below the MTJ, in contrast to the top SOT stack configuration of FIG. 6.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure generally relates to topological material based spin-orbit torque (SOT) devices. The SOT device comprises a seed layer, a texture layer disposed on the seed layer, a first barrier layer disposed on the texture layer, a ferromagnetic (FM) layer disposed over the first barrier layer, a topological insulator (TI) or topological semi-metal (TSM) layer disposed over the first barrier layer, the TI or TSM layer comprising YPtBi or BiSb, and a second barrier layer disposed between the FM layer and the TI or TSM layer. In one embodiment, the texture layer, the first and second barrier layers, and the FM layer have a (100) orientation, and the TI or TSM layer comprises (012) BiSb or (100) YPtBi. In another embodiment, the texture layer, the first and second barrier layers, and the FM layer have a (110) orientation, and the TI or TSM layer comprises (110) YPtBi.

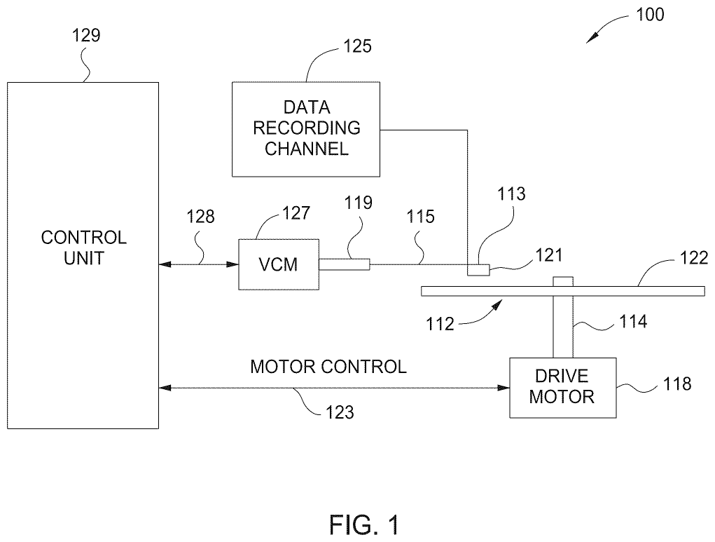

FIG. 1 is a schematic illustration of certain embodiments of a magnetic media drive 100 including a magnetic recording head having a SOT MTJ device. Such a magnetic media drive may be a single drive or comprise multiple drives. For the sake of illustration, a single disk drive 100 is shown according to certain embodiments. As shown, at least one rotatable magnetic disk 112 is supported on a spindle 114 and rotated by a drive motor 118. The magnetic recording on each magnetic disk 112 is in the form of any suitable patterns of data tracks, such as annular patterns of concentric data tracks (not shown) on the magnetic disk 112.

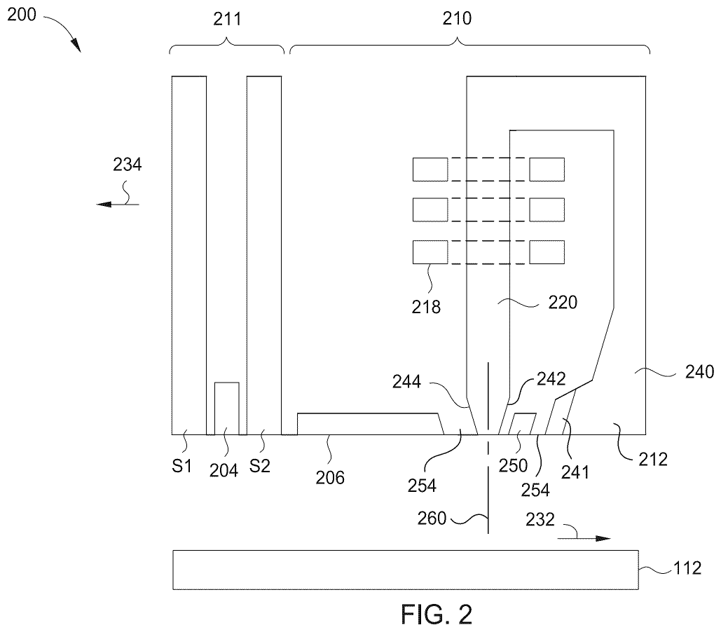

At least one slider 113 is positioned near the magnetic disk 112, each slider 113 supporting one or more magnetic head assemblies 121 that include a SOT device. As the magnetic disk 112 rotates, the slider 113 moves radially in and out over the disk surface 122 so that the magnetic head assembly 121 may access different tracks of the magnetic disk 112 where desired data are written. Each slider 113 is attached to an actuator arm 119 by way of a suspension 115. The suspension 115 provides a slight spring force which biases the slider 113 toward the disk surface 122. Each actuator arm 119 is attached to an actuator means 127. The actuator means 127 as shown in FIG. 2 may be a voice coil motor (VCM). The VCM includes a coil movable within a fixed magnetic field, the direction and speed of the coil movements being controlled by the motor current signals supplied by control unit 129.

During operation of the disk drive 100, the rotation of the magnetic disk 112 generates an air bearing between the slider 113 and the disk surface 122 which exerts an upward force or lift on the slider 113. The air bearing thus counter-balances the slight spring force of suspension 115 and supports slider 113 off and slightly above the disk surface 122 by a small, substantially constant spacing during normal operation.

The various components of the disk drive 100 are controlled in operation by control signals generated by control unit 129, such as access control signals and internal clock signals. Typically, the control unit 129 comprises logic control circuits, storage means and a microprocessor. The control unit 129 generates control signals to control various system operations such as drive motor control signals on line 123 and head position and seek control signals on line 128. The control signals on line 128 provide the desired current profiles to optimally move and position slider 113 to the desired data track on disk 112. Write and read signals are communicated to and from write and read heads on the assembly 121 by way of recording channel 125.

The above description of a typical magnetic media drive and the accompanying illustration of FIG. 1 are for representation purposes only. It should be apparent that magnetic media drives may contain a large number of media, or disks, and actuators, and each actuator may support a number of sliders.

FIG. 2 is a fragmented, cross-sectional side view of certain embodiments of a read/write head 200 having a SOT device. The read/write head 200 faces a magnetic media 112. The read/write head 200 may correspond to the magnetic head assembly 121 described in FIG. 1. The read/write head 200 includes a media facing surface (MFS) 212, such as a gas bearing surface, facing the disk 112, a write head 210, and a magnetic read head 211. As shown in FIG. 2, the magnetic media 112 moves past the write head 210 in the direction indicated by the arrow 232 and the read/write head 200 moves in the direction indicated by the arrow 234.

In some embodiments, the magnetic read head 211 is a magnetoresistive (MR) read head that includes an MR sensing element 204 located between MR shields S1 and S2. In other embodiments, the magnetic read head 211 is a magnetic tunnel junction (MTJ) read head that includes a MTJ sensing device 204 located between MR shields S1 and S2. The magnetic fields of the adjacent magnetized regions in the magnetic disk 112 are detectable by the MR (or MTJ) sensing element 204 as the recorded bits. The SOT device of various embodiments can be incorporated into the read head 211 as the sensing element. An example of an SOT read head is described in co-pending patent application titled “Topological Insulator Based Spin Torque Oscillator Reader,” U.S. application Ser. No. 17/828,226, filed May 31, 2022, assigned to the same assignee of this application, which is herein incorporated by reference. Another example of an SOT read head is described in co-pending patent applications titled “Non-Localized Spin Valve Reader Hybridized With Spin Orbit Torque Layer,” U.S. application Ser. No. 18/367,877, filed Sep. 13, 2023, and “Non-Localized Spin Valve Multi-Free-Layer Reader Hybridized With Spin Orbit Torque Layers,” U.S. application Ser. No. 18/367,882, filed Sep. 13, 2023, both of which are herein incorporated by reference.

The write head 210 includes a main pole 220, a leading shield 206, a trailing shield 240, an optional spin orbital torque (SOT) device 250, and a coil 218 that excites the main pole 220. The coil 218 may have a “pancake” structure which winds around a back-contact between the main pole 220 and the trailing shield 240, instead of a “helical” structure shown in FIG. 2. When included, e.g., to achieve a Microwave Assisted Magnetic Recording (MAMR) effect, the SOT device 250 is formed in a gap 254 between the main pole 220 and the trailing shield 240. The main pole 220 includes a trailing taper 242 and a leading taper 244. The trailing taper 242 extends from a location recessed from the MFS 212 to the MFS 212. The leading taper 244 extends from a location recessed from the MFS 212 to the MFS 212. The trailing taper 242 and the leading taper 244 may have the same degree of taper, and the degree of taper is measured with respect to a longitudinal axis 260 of the main pole 220. In some embodiments, the main pole 220 does not include the trailing taper 242 and the leading taper 244. Instead, the main pole 220 includes a trailing side (not shown) and a leading side (not shown), and the trailing side and the leading side are substantially parallel. The main pole 220 may be a magnetic material, such as a FeCo alloy. The leading shield 206 and the trailing shield 240 may be a magnetic material, such as a NiFe alloy. In certain embodiments, the trailing shield 240 can include a trailing shield hot seed layer 241. The trailing shield hot seed layer 241 can include a high moment sputter material, such as CoFeN, FeXN, or FeX, where X includes at least one of N, AI, Ni, Co, Ta, Re, Ir, Pt, Rh, Ta, Zr, and Ti. In certain embodiments, the trailing shield 240 does not include a trailing shield hot seed layer. In other embodiments, instead of an SOT device 250 it may be a conductive stack in the write gap. In certain embodiments, the read/write head 200 additionally includes mechanisms (not shown) for supporting Heat Assisted Magnetic Recording (HAMR), which may include a waveguide coupled to a light source and a near field transducer (NFT) placed adjacent to the main pole 220 and coupled to the waveguide to convert the delivered light into a heating spot on the media.

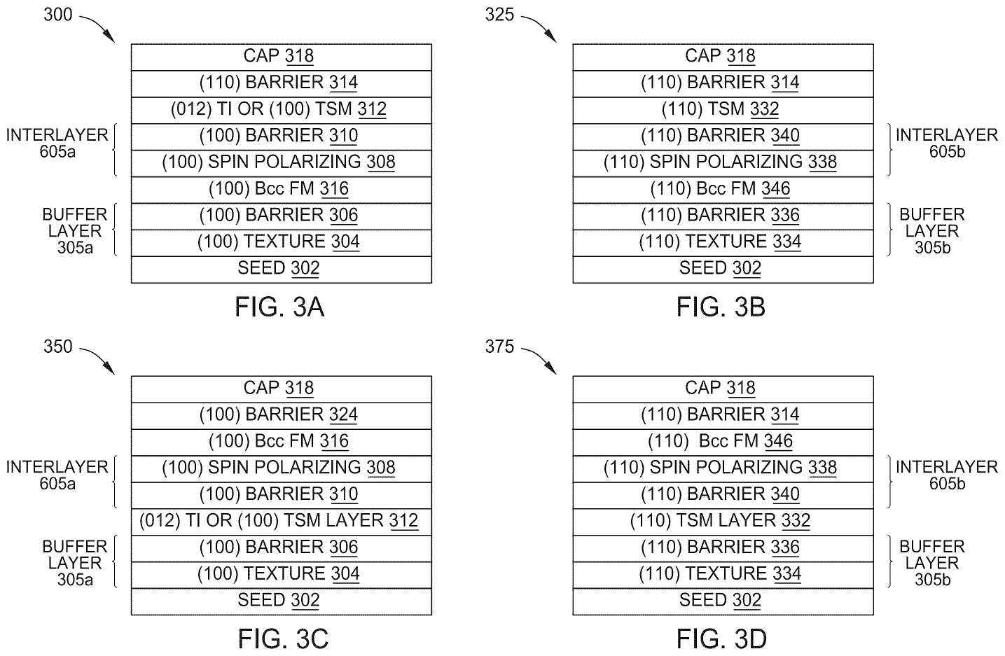

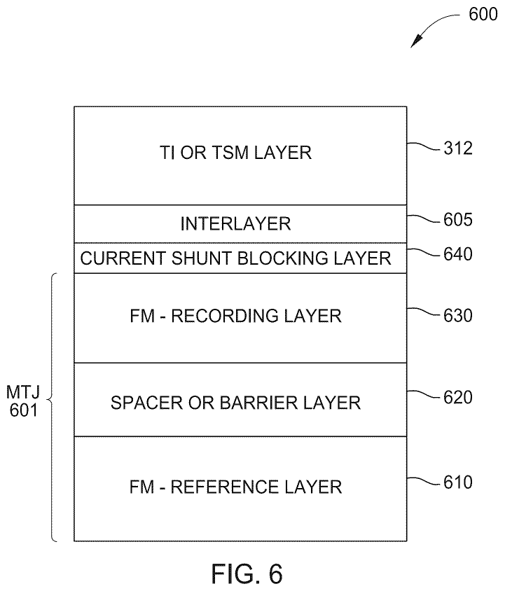

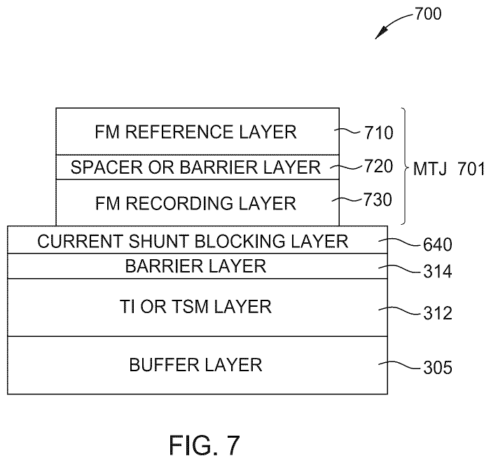

FIGS. 3A-3D illustrate spin orbit torque (SOT) devices 300, 325, 350, 375, respectively, according to various embodiments. The SOT devices 300, 325, 350, 375 may each individually be used in the MAMR recording head of the drive 100 of FIG. 1, in the reader, and/or writer portions of the head 200 of FIG. 2, or other suitable magnetic media drives. The SOT devices 300, 325, 350, 375 may each individually be an MTJ in sensors or used in MRAM applications, such as the example MRAM embodiments disclosed in FIGS. 6 and 7, and spin-charge conversion layers/structures in logic circuit that can be used as neuromorphic, neuron elements or other machine learning/computational elements as part of artificial intelligence chips. Other applications include magnetic sensors via a direct or indirect spin Hall effect, and spin Hall oscillators.

The SOT device 300 of FIG. 3A comprises a seed layer 302, a (100) texture layer 304 disposed on the seed layer 302, a (100) barrier layer 306 disposed on the (100) texture layer 304, a (100) ferromagnetic (FM) layer 316 disposed on the (100) barrier layer 306, an optional (100) spin polarizing layer 308 disposed on the (100) FM layer 316, a (100) barrier layer 310 disposed on the (100) polarization layer 308, a (012) topological insulator (TI) or a (100) topological semi-metal (TSM) layer 312 disposed on the (100) barrier layer 310, an optional (110) barrier layer 314 disposed on the (012) TI or (100) TSM layer 312, and a cap layer 318 disposed on the (110) barrier layer 314. The (012) TI or (100) TSM layer 312 comprises (012) BiSb or (100) YPtBi. The (012) TI or (100) TSM layer 312 may be doped or undoped. The (012) TI or (100) TSM layer 312 may be referred to herein as an SOT layer. The (100) texture layer 304 and the (100) barrier layer 306 form a buffer layer 305a. The (100) spin polarizing layer 308 and the (100) barrier layer 310 form an interlayer 605a.

The SOT device 325 of FIG. 3B comprises the seed layer 302, a (110) texture layer 334 disposed on the seed layer 302, a (110) barrier layer 336 disposed on the (110) texture layer 334, a (110) FM layer 346 disposed on the (110) barrier layer 336, an optional (110) polarization layer 338 disposed on the (110) FM layer 346, a (110) barrier layer 340 disposed on the (110) spin polarizing layer 338, a (110) TSM layer 332 disposed on the (110) barrier layer 340, the optional barrier layer 314 disposed on the (110) TSM layer 332, and the cap layer 318 disposed on the third barrier layer 314. The (110) TSM layer 332 comprises doped or undoped YPtBi. The (110) TSM layer 332 may be referred to herein as an SOT layer. The SOT devices 300 and 325 are top SOT stacks. The (110) texture layer 334 and the (110) barrier layer 336 form a buffer layer 305b. The (110) spin polarizing layer 338 and the (110) barrier layer 340 form an interlayer 605b.

The SOT device 350 of FIG. 3C comprises the seed layer 302, the (100) texture layer 304 disposed on the seed layer 302, the (100) barrier layer 306 disposed on the (100) texture layer 304, the (012) TI or (100) TSM layer 312 disposed on the (100) barrier layer 306, the (100) barrier layer 310 disposed on the (012) TI or (100) TSM 312 layer, the optional (100) spin polarizing layer 308 disposed on the (100) barrier layer 310, the (100) FM layer 316 disposed on the (100) polarization layer 308, an optional (100) barrier layer 324 disposed on the (100) FM layer 316, and the cap layer 318 disposed on the (100) barrier layer 324. The (100) spin polarizing layer 308 and the (100) barrier layer 310 form an interlayer 605a.

The SOT device 375 of FIG. 3D comprises the seed layer 302, the (110) texture layer 334 disposed on the seed layer 302, the (110) barrier layer 336 disposed on the (110) texture layer 334, the (110) TSM layer 332 disposed on the (110) barrier layer 336, the (110) barrier layer 340 disposed on the (110) TSM 332 layer, the optional (110) spin polarizing layer 338 disposed on the (110) barrier layer 340, the (110) FM layer 346 disposed on the (110) polarization layer 338, the optional (110) barrier layer 314 disposed on the (110) FM layer 346, and the cap layer 318 disposed on the (110) barrier layer 314. The SOT devices 350 and 375 are bottom SOT stacks. The (110) spin polarizing layer 338 and the (110) barrier layer 340 form an interlayer 605b.

The texture layers 304, 334 generate the crystalline symmetry layers. The texture layer 304 generating a (100) texture: comprise (1) B2 binary alloys X-Al, generally deposited at temperatures >150° C., where X is one or more of Co, Ni, Ru, Rh, and Ir; (2) heated bcc metals or alloys like Cr or CrX alloys, where X is one or more of Mo, Mn, Ti, Ru, and W (with a-axis lattice parameters in the range of about 2.87 Å to about 3.08 Å); (3) room temperature lamination of RuAl, W-X, or Ta—X alloys with MgO and TiO, where, for example, X is one or more of Ta, Hf, W, V, Ti, Nb and Mo; or (4) in any combination with other materials, such as B2 or bcc alloys like RuAl, RhAl, CrMo, and TaW, etc.

Bcc metals and alloys can generate the texture layer 334 generating a (110) texture as they tend to grow films in the close-packed (110) growth direction. Nanocrystalline conditioning or seed layers (like NiFeW, Ru, NiFeTa, CoFeTa, and NiFeGe), in combination with crystalline seed layers (like hcp Ru), or bcc alloy layers (like CrX alloys (where X is one or more of V, Ti, Ni, Co, Fe, Nb, Mo, Ta, and W), can all be used to enhance the (110) growth texture of larger lattice parameter bcc metals or alloys (like V, Nb, Mo, Ta, W, CrMo, TaW, TaHf, RuTa, etc.). Materials selected from these two texture layer 304, 334 groups can be used to produce other (100) or (110) texture layers. Like bcc metals or alloys with a-axis lattice parameters in the range of 2.87 Å to about 3.38 Å, some examples of which are Ta, W, Mo, Nb, V, or alloys like WTi and CrMo, or B2 metals with the same lattice parameter range like binary alloys like RhAl, IrAl, and NiAl, all of which can serve to directly lattice match and epitaxially grow the TI or TSM layers 312, 332 or FM layers 316, 346 (which are preferably bcc), or through the use of an intermediate epitaxial barrier layer.

The barrier layers 306, 310, 314, 324, 336, and 340 offer some elemental migration resistance or serve as higher resistance shunt blocking layers or, ideally, both. The barrier layers 306, 310, 314, 324, 336, and 340 can be selected from 3 different nonmagnetic type material groups.

The first group of materials for the barrier layers 306, 310, 314, 324, 336, and 340 includes these options: (1) high lattice parameter, higher resistance, atomically ordered B2 (AB) binary alloys like RuHf and Zr—X alloys, where X is one or more of Co, Cu, Ru, and Rh; (2) Ti—Y alloys, where Y is one or more of Au, Ru, and Rh; B2 ternary A (BₓC₁₋ₓ) alloys, like (HfTi).5Ru, Ru (AIV).5, (AlMo).5Ti, and CoZrX, where X is one or more of Ti, Fe, Ni, Nb, and Mo (e.g., (Co(Ti.3Zr.7), (Co.8Fe.2) Zr, (CoNi).5Zr, and Co(Nb.25Zr.75)); or (3) disordered binary or ternary or higher bcc alloys where multiple elements are selected to form a bcc alloy from the group consisting of Ta, Hf, W, Ir, Pt, Y, Zr, Nb, Mo, Mg, Sc, Ti, V, Cr, Fe, Co, Ni, Cu, Ru, Rh, and Ag. The first group of materials for the barrier layers 306, 310, 314, 324, 336, and 340 all have lattice parameters in the range of 2.87 Å to 3.38 Å.

The second group of materials for the barrier layers 306, 310, 314, 324, 336, and 340 is fcc materials with lattice parameters about 4.08 Å to 4.75 Å, such as oxides of Ti, Mg, Ni, Zn, or Zr; or X-N or X-C composites, where X is one or more of Sc, Ti, V, Cr, Zr, Nb, Ta, Hf, and W, as well as alloy composites of the above.

The third group of materials for the barrier layers 306, 310, 314, 324, 336, and 340 is tetragonal oxides with a-axis lattice parameters in a range of 4.35 Å to 4.75 Å and c-axis in the range of 2.85 Å to 3.19 Å, like MO₂ materials, examples of which are where M is one or more of Ti, Cr, Ru, Rh, Sn, Sb, Ir, CrNb, CrV, and WV alloys, or any combination composites thereof.

The first two groups of materials for the barrier layers 306, 310, 314, 324, 336, and 340 can be used with either (100) or (110) texture layers 304, 334 to form (100) or (110) textured barrier layers 306, 310, 314, 324, 336, and 340. The texturing of the third group of barrier layers 306, 310, 314, 324, 336, and 340 (i.e., the MO₂ tetragonal oxides) will depend on the texturing layer type. The (100) texturing layer 304 produces (001) textured MO₂ tetragonal oxides, which in turn can be used to create (100) textures in other layers. The (110) texturing layer 334 create a (110) texture for a number of tetragonal MO₂ oxide layer, but only for oxides where the a/c ratio is near the sqrt (2), like where M is one or more of Os, Ir, Ru, Rh, Sn, Sb, and Pd. It is also possible for (110) texturing layers to lattice match to these MO₂ oxides with a/c˜sqrt (2), along the (100) or (010) MO₂ growth directions, which then will lattice match to a (110) TSM textured layer surface. While the (100) and (010) matches are simpler, they are slightly more difficult to grow than (001) and (110); however, the (100) and (010) textured MO₂ layers are possible to produce.

The barrier layers 306, 310, 314, 324, 336, and 340 are generally used between the texture layer and either the FM in a top SOT stack, such as the SOT devices 300 and 325; the texture layer and the TI or TSM layer in a bottom SOT stack, such as the SOT devices 350 and 375; between the TI or TSM layer and the FM layer; or between the TI or TSM layer or the FM layer and the cap layers. The barrier layers 306, 310, 314, 324, 336, and 340 can be combined with other barrier layers to reduce strain or enhance migration resistance or electrical shunting between layers. Bilayer examples include a B2 or bcc alloy/fcc ceramic oxide, nitride, or carbide bilayers, like NiAl/MgO, RuAl/TiO, TaW/TaC, and TaW/WN (“/” denoting layer separation), and trilayer combinations based on similar materials can also be used in various embodiments.

For (100) textured SOT devices (i.e., the SOT devices 300 and 350 in FIGS. 3A and 3C), epitaxial growth can be formed with (012) textured TI layers like BiSbX (where X is a dopant), or with (100) textured TSM layers like YPtBi. However, epitaxial growth with (110) textured layers can only be done with (110) textured TSM layers like YPtBi (i.e., SOT devices 325 and 375 in FIGS. 3B and 3D).

The spin polarizing layers 308, 338 disposed between the FM layers 316, 346 and the TI or TSM layers 312, 332, where the spin polarizing layers 308, 338 are disposed adjacent to the FM layers 316, 346, enhance the spin current. FM layers 316, 346 comprising bcc CoFeX (where X can be used to increase the lattice parameter of the FM alloys) can epitaxially be matched to standard Heusler alloys in the a-axis range of 5.7 Å to 6.0 Å, like Co₂MnGe. However, either half metallic or full large lattice parameter Heusler alloy materials are needed with larger lattice parameters having an a-axis in the range of 6.0 Å to 6.7 Å (like MnSbPt (6.20 Å), Sc₂VGe (6.65 Å), or PdSnY (6.70 Å)), or other cubic materials within the space group 216 having a similar lattice parameters range, such as YNiBi, YPdBi, NiBiGd, AgMgSb, and BiXPt alloys, where X is a rare earth materials from Gd to Lu.

Those skilled in the art can grow bcc metals along the close-packed direction, creating strong (110) textured bcc or bcc alloy films mentioned above with lattice parameters in the range of 2.87 Å to 3.38 Å, by using combinations of nanocrystalline conditioning layers and other bcc seed layer materials or alloys like the Cr—X alloys mentioned above, or by using thin (001) hcp Ru seed layers. These highly textured (110) bcc or bcc alloy films can then be used to grow fcc (110) textured barrier layer films with lattice parameters of about 4.08 Å to 4.75 Å mentioned above, or (110) textured binary, ternary, or higher B2 alloys mentioned above, which can be utilized as high resistance or migration barrier layers 314, 336, and 340 in SOT devices 325 and 375, and in the case of barrier layers 336 and 340, on which to grow (110) textured YPtBi TSM layer 332. (110) textured barrier layers of (110) textured MO₂ oxides could also be used for those oxides that have a/c ratios near the sqrt (2), as mentioned above.

Those skilled in the art can also grow bcc metals or B2 materials and alloys with a strong (100) texture and lattice parameters in the range of about 2.9 Å to 3.4 Å, like those of RuAl or the heated Cr—X alloys mentioned above, or at room temperature by lamination of RuAl with MgO, or MgO and W, W-alloys, or in combination with room temperature RuAl layers. These (100) texture layers can be used as options for the texture layer 304, which can be used to grow strong fcc (100) textured barrier layers (e.g., the barrier layer 306) with lattice parameters in the range of 4.08 Å to 4.75 Å mentioned above, or (001) textured MO₂ tetragonal oxides mentioned above with axis lattice parameters in the 4.08 Å to 4.75 Å range.

Barrier layers (e.g., barrier layers 306 and 310) disposed between the textured seed layers and the TI or TSM layers 312, 332 can, in general, offer better control of electrical shunting between the seed layer 302 and the TI or TSM layer 312, 332; or can serve as migration barrier layers to prevent intermixing of the TI or TSM layers 312, 332 and seed layer 302; or provide better film epitaxial growth to the TI or TSM layers 312, 332.

Layers that are not useful to grow epitaxially strong (012) textured BiSbX SOT layers include the following: (110) texture layers; fcc layers, which are in the lower a-axis range 4.08 Å to about 4.6 Å; bcc or B2 alloys with a-axis ranges around 2.9 Å to about 3.2 Å; fcc Heuslers or spinels with lattice parameters in the range of about 5.9 Å to about 6.4 Å; or (001) MO₂ oxides mentioned above with a-axis below about 4.5 Å. The (100) texture layer serves the same purpose as mentioned above for SOT layers comprising YPtBi to better control electrical shunting and elemental intermixing between the seed or buffer layers, and to provide potentially better epitaxial growth of BiSbX SOT layers.

High resistance binary or ternary, or higher B2 alloy, texture layers offer additional manufacturability options to fcc layers to improve epitaxial growth and impede migration or reduce shunting of seed layers, barrier layers, FM layers, and/or SOT layers, or between the SOT layers and the FM layer and/or cap layer.

The (100) and (110) spin polarizing layer 308 may comprise Heusler alloys like Co₂MnGe, Co₂FeAl, or a higher lattice parameter Heusler alloy. The seed layer 302 may comprise a nanocrystallinematerials, such as NiFeGe, NiAlGe, NiTa, NiFeTa, and NiFeW, or crystalline layers, such as Ru, Cr, or CrX alloys. For the CrX alloy option for the seed layer 302, if it is for embodiments with the (100) spin polarizing layer, X is one or more of Mo, Mn, Ti, Ru, and W. If it is for embodiments with the (110) spin polarizing layer, X is one or more of V, Ti, Ni, Co, Fe, Ta, W, Mo, Nb, V, WTi, CrMo, RhAl, IrAl, and NiA.

The FM layers 316, 346 each has a thickness of about 5 Å to about 15 Å, and may comprise NiFe, CoFe, NiFeX, CoFeX, FeX, CoX, or NiX, where X is one or more of Co, Ni, Cu, Si, Al, Mn, Ge, Ta, Hf, N, Pt, Ir, and B. The FM layers 316, 346 may each comprise any magnetic layer combination or alloy combination of these elements that can yield a low coercivity, negative magnetostrictive FM layer 316, 346 or in multilayer combinations with other higher polarizing materials like Heusler alloys or high Ni containing alloy FM layers. The FM layers 316, 346 may preferably comprise a bcc material, as it would be parallel to the (100) MgO crystal axis.

The cap layer 318 and the seed layer 302 need not be crystalline. The cap layer 318 and the seed layer 302 may each individually comprise amorphous or nanocrystalline layers like NiAlGe or NiFeGe. The cap layer 318 may comprise non-magnetic, high resistivity materials, such as: thin ceramic oxides or nitrides of TIN, SIN, MgTiO, and MgO; amorphous/nanocrystalline metals such as NiFeGe, NiFeTa, NiTa, NiHf, NiFeHf, CoHf, CoFeHf, NiWTa, NiFeW, NiW, or WRe; or nitrides, oxides, or borides of above-mentioned elements, compounds, and/or alloys such as NiTaN, NiFeTaN, NiWTaN, NiWN, WReN, TaN, WN, TaOx, WOx, WB, HfB, NiHfB, NiFeHfB, CoHfB, and CoFeHfB, where x is a numeral. In some embodiments, lower atomic number (Z) materials are preferred in the cap layer 318 to reduce sputter intermixing with the FM layer 316 or 366, but high Z alloys can be used, if used in combination with a migration barrier beneath, or if the high Z elements are used with a high resistive oxide, nitride, or boride. The cap layer 318 can comprise multilayer combinations of the above-mentioned materials, and the overall thickness of the cap layer 318 is less than or equal to about 100 Å (nominally about 15 Å to about 50 Å).

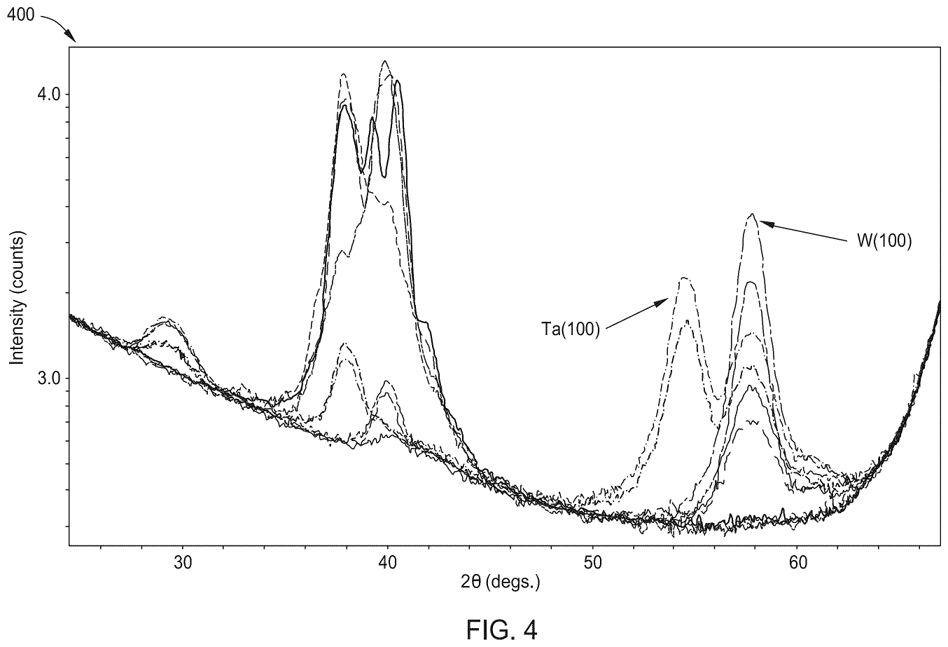

FIG. 4 illustrates a graph 400 showing examples of texture layers which could be used to produce a YPtBi (100) texture and/or a BiSb (012) texture, according to one embodiment. As shown, both Ta and W have a strong (100) orientation, resulting in YPtBi having a (100) orientation, when used as a texture layer, such as the texture layer 304 of FIG. 3A and/or the texture layer 334 of FIG. 3B.

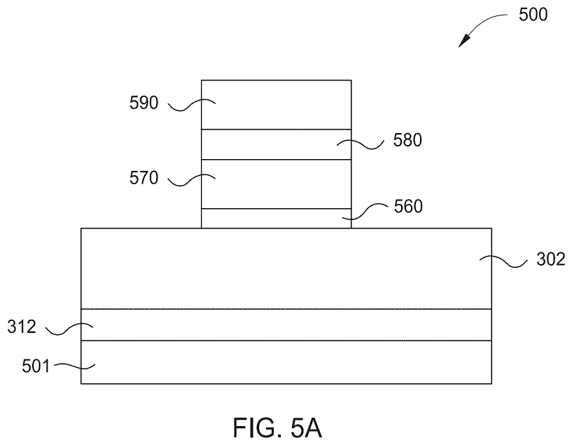

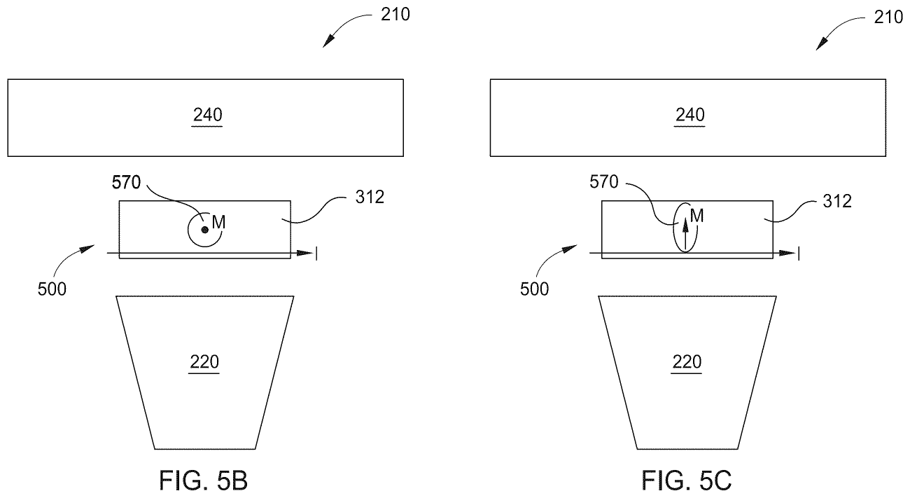

FIG. 5A is a schematic cross-sectional view of a SOT device 500 for use in a MAMR magnetic recording head, such as the MAMR magnetic recording head of the drive 100 of FIG. 1 or other suitable magnetic media drives. The SOT device 500 comprises a TI or TSM layer 312 orientation formed over a buffer layer 305 formed over a substrate 501, such as the TI or TSM layer 312 and the buffer layer 305a of FIG. 3A or 3C, and/or the TI layer 332 and the buffer layer 305b of FIG. 3B or 3D. Thus, the TI or TSM layer 312 may comprise YPtBi having a (100) orientation, YPtBi having a (110) orientation, or BiSb having a (012) orientation. A spin torque layer (STL) 570 is formed over the TI or TSM layer 312. The STL 570 comprises a ferromagnetic material such as one or more layers of CoFe, Colr, NiFe, and CoFeX alloy wherein X=B, Ta, Re, or Ir.

In certain embodiments, an electrical current shunt blocking layer 560 is disposed between the TI or TSM layer 312 and the STL 570. The electrical current shunt blocking layer 560 reduces electrical current from flowing from the TI or TSM layer 312 to the STL 570 but allows spin orbital coupling of the TI or TSM layer 312 and the STL 570. In certain embodiments, the electrical current shunt blocking layer 560 comprises a magnetic material which provides greater spin orbital coupling between the TI or TSM layer 312 and the STL 570 than a non-magnetic material. In certain embodiments, the electrical current shunt blocking layer 560 comprises a magnetic material of FeCo, FeCOM, FeCOMO, FeCoMMeO, FeCOM/MeO stack, FeCoMNiMnMgZnFeO, FeCOM/NiMnMgZnFeO stack, multiple layers/stacks thereof, or combinations thereof in which M is one or more of B, Si, P, Al, Hf, Zr, Nb, Ti, Ta, Mo, Mg, Y, Cu, Cr, and Ni, and Me is Si, Al, Hf, Zr, Nb, Ti, Ta, Mg, Y, or Cr. In certain embodiments, the electrical current shunt blocking layer 560 is formed to a thickness from about 10 Å to about 100 Å. In certain aspects, an electrical current shunt blocking layer 560 having a thickness of over 100 Å may reduce spin orbital coupling of the TI or TSM layer 312 and the STL 570. In certain aspects, an electrical current shunt blocking layer having a thickness of less than 10 A may not sufficiently reduce electrical current from TI or TSM layer 312 to the STL 570.

In certain embodiments, additional layers are formed over the STL 570 such as a spacer layer 580 and a pinning layer 590. The pinning layer 590 can partially pin the STL 570. The pinning layer 590 comprises a single or multiple layers of PtMn, NiMn, IrMn, IrMnCr, CrMnPt, FeMn, other antiferromagnetic materials, or combinations thereof. The spacer layer 580 comprises single or multiple layers of magnesium oxide, aluminum oxide, other non-magnetic materials, or combinations thereof.

FIGS. 5B-5C are schematic MFS views of certain embodiments of a portion of a MAMR magnetic recording head 210 with a SOT device 500 of FIG. 5A. The MAMR magnetic recording head 210 can be the magnetic recording head FIG. 2 or other suitable magnetic recording heads in the drive 100 of FIG. 1 or other suitable magnetic media drives such as tape drives. The MAMR magnetic recording head 210 includes a main pole 220 and a trailing shield 240 in a track direction. The SOT device 500 is disposed in a gap between the main pole and the trailing shield 240.

During operation, charge current through a TI or TSM layer 312 acting as a spin Hall layer generates a spin current in the TI or TSM layer. The spin orbital coupling of the TI or TSM layer and a spin torque layer (STL) 570 causes switching or precession of magnetization of the STL 570 by the spin orbital coupling of the spin current from the TI or TSM layer 312. Switching or precession of the magnetization of the STL 570 can generate an assisting AC field to the write field. Energy assisted magnetic recording heads based on SOT have multiple times greater power efficiency in comparison to MAMR magnetic recording heads based on spin transfer torque. As shown in FIG. 5B, an easy axis of a magnetization direction of the STL 570 is perpendicular to the MFS from shape anisotropy of the STL 570, from the pinning layer 590 of FIG. 5A, and/or from hard bias elements proximate the STL 570. As shown in FIG. 5C, an easy axis of a magnetization direction of the STL 570 is parallel to the MFS from shape anisotropy of the STL 570, from the pinning layer 590 of FIG. 5A, and/or from hard bias elements proximate the STL 570.

FIGS. 6 and 7 show a top SOT MRAM device and a bottom SOT MRAM device respectively, according to various embodiments.

FIG. 6 is a schematic cross-sectional view of a magnetic tunnel junction (MTJ) 601 used as a top SOT MRAM device 600, according to one embodiment. The MRAM device 600 comprises an MTJ 601, which includes a ferromagnetic (FM) reference layer (RL) 610, a spacer or barrier layer 620 over the RL 610, an FM recording layer 630 over the spacer or barrier layer 620. In addition, the MRAM device 600 comprises an interlayer 605 over an electrical current shunt blocking layer 640 over the recording layer 630 of the MTJ 601, and a TI or TSM layer 332 over the interlayer 605. The interlayer provides a means to transfer the material structure symmetry from the underlying layers of the MTJ to the TI or TSM layer. This is in contrast to the buffer layer used in FIG. 7, which is necessary to set the material structure and grow the TI or TSM layer in the bottom SOT configuration. The TI or TSM layer 312 may be the TI or TSM layer 312 and the interlayer of FIGS. 3A-3B. The interlayer 605 corresponds to the interlayer 605a or 605b in FIGS. 3A-3B, and may comprise the material options for the barrier layer 310/340 and the spin polarizing layer 308/338 described above.

The barrier layer within the interlayer may comprise the material options of MgO and NiFeGe (e.g., layer may comprise MgO or NiFeGe). It may also include the material options for the buffer layer as noted above. In addition, the FM recording layer 630 corresponds to the FM layer 316 in FIG. 3A or the FM layer 346 in FIG. 3B, except that, unlike in FIGS. 3A and 3B, this top SOT configuration in FIG. 6 has the TI or TSM layer and interlayer disposed over the FM layer 316 (FM recording layer 630). Other layers such as the seed or cap layer in FIGS. 3A-3D above may be optionally included here but not shown.

The RL 610 comprises single or multiple layers of CoFe, other ferromagnetic materials, and combinations thereof. The spacer or barrier layer 620 comprises single or multiple layers of magnesium oxide (MgO), aluminum oxide, other dielectric materials, or combinations thereof. The recording layer 630 comprises single or multiple layers of CoFe, NiFe, other ferromagnetic materials, or combinations thereof, or may comprise material options noted above for the FM layer 316.

As noted above, in certain embodiments, the electrical current shunt blocking layer 640 is disposed between the interlayer 605 and the recording layer 630. The electrical current shunt blocking layer 640 reduces electrical current from flowing from the TI or TSM layer 312 to the recording layer 630 but allows spin orbital coupling of the TI or TSM layer 312 and the recording layer 630. For example, writing to the MRAM device can be enabled by the spin orbital coupling of the TI or TSM layer and the recording layer 630, which enables switching of magnetization of the recording layer 630 by the spin orbital coupling of the spin current from the TI or TSM layer 312. In certain embodiments, the electrical current shunt blocking layer 640 comprises a magnetic material which provides greater spin orbital coupling between the TI or TSM layer 312 and the recording layer 630 than a non-magnetic material. In certain embodiments, the electrical current shunt blocking layer 640 comprises a magnetic material of FeCOM, FeCOMO, FeCoMMeO, FeCOM/MeO stack, FeCoMNiMnMgZnFeO, FeCOM/NiMnMgZnFeO stack, multiple layers/stacks thereof, or combinations thereof, in which M is one or more of B, Si, P, Al, Hf, Zr, Nb, Ti, Ta, Mo, Mg, Y, Cu, Cr, and Ni, and Me is Si, Al, Hf, Zr, Nb, Ti, Ta, Mg, Y, or Cr.

The MRAM device 600 of FIG. 6 may include other layers, such as pinning layers, pinning structures (e.g., a synthetic antiferromagnetic (SAF) pinned structure), electrodes, gates, and other structures. It is noted that, in other embodiments, the MRAM device may include the TI or TSM layer 312 at the bottom of the stack.

FIG. 7 is a schematic cross-sectional view of another MRAM device 700 according to one embodiment, which has a bottom SOT stack configuration, with a TI or TSM bottom layer below the MTJ, in contrast to the top SOT stack configuration of FIG. 6.

As illustrated in FIG. 7, the MRAM device 700 includes a buffer layer 305, a TI or TSM layer or layer 312 over the buffer layer 305, an interlayer 605 over the TI or TSM layer 312, an electrical current shunt blocking layer 640 over the barrier layer 314, and an MTJ 701 over the electrical current shunt blocking layer 640. The MTJ 701 includes an FM recording layer 730, a spacer or barrier layer 720 over the FM recording layer 730, and an FM reference layer (RL) 710 over the spacer or barrier layer 720.

The TI or TSM layer 312 and the buffer layer 305 may be the TI or TSM layer 312 and the buffer layer 305a of FIG. 3C or the TI layer 332 and the buffer layer 305b of FIG. 3D. Thus, the TI or TSM layer 312 may comprise YPtBi having a (100) orientation, YPtBi having a (110) orientation, or BiSb having a (012) orientation. The interlayer 605 corresponds to the interlayer 605a or 605b in FIGS. 3C-3D, and may comprise the material options for the barrier layer 310/340 and the spin polarizing layer 308/338 described above. The barrier layer within the interlayer may comprise the material options of MgO and NiFeGe (e.g., layer may comprise MgO or NiFeGe). It may also include the material options for the buffer layer as noted above. The layers of the MTJ and the electrical current shunt blocking layer of FIG. 7 otherwise correspond to those of FIG. 6 and may comprise the above described material options. Other layers such as the seed or cap layer in FIGS. 3A-3D above may be optionally included here but not shown. Like in FIG. 6, the MRAM device 700 of FIG. 7 may include other layers, such as pinning layers, pinning structures (e.g., a synthetic antiferromagnetic (SAF) pinned structure), electrodes, gates, and other structures.

Generally speaking, in either of the MRAM device 600 or 700, the TI or TSM layer 312 serves as a spin injection source to write data in the MRAM device, whereby a current flowing in a plane of the TI or TSM layer causes a spin current in a direction perpendicular to the plane. Then, the spin current causes switching of the magnetic orientation of the recording layer 630 or 730, reflecting storage of a data bit. The magnetic orientation of the recording layer 630 or 730 relative to that of the reference layer 610 or 710 determines the resistance of the MTJ 601 or 701, enabling the read out of that stored data bit value. The MRAM device 600 or 700 may be implemented as a two or three terminal device.

In certain embodiments, the MRAM device 600 or 700 may be configured as part of a neuromorphic array, through which individual MRAM devices are configured to store weights for machine learning computational purposes (e.g., multiply-accumulate operations). An example of such an array is disclosed in co-pending application titled “Matrix-Vector Multiplication Using SOT-based Non-Volatile Memory Cells,” U.S. application Ser. No. 17/172,155, filed Feb. 10, 2021, the disclosure of which is hereby incorporated by reference. In other embodiments, the material stack configurations of FIGS. 6 and 7 may be part of a spin Hall oscillator instead of an MRAM device, where the recording layer 610 or 710 becomes instead a spin oscillator layer. It is caused to precess by the spin current from the TI or TSM layer 312. A controlled current source into the TI or TSM layer enables control of the oscillation from the spin Hall oscillator device. The mechanism is similar to the MAMR recording head embodiment of FIGS. 5A-5C described above.

In other embodiments, the SOT device of FIGS. 3A-3D are embodied in other applicable spin-to-charge or charge-to-spin conversion use cases. As an example, they can be used in machine learning applications such as those disclosed in co-pending application titled “Spin Orbital Squared (SO-SO) Logic,” U.S. application Ser. No. 18/645,189, filed Apr. 24, 2024, co-pending application titled “Deep Neural Network Device Based on Dual Spin Orbit Torque (SOT) Devices,” U.S. application Ser. No. 18/645,195, filed Apr. 24, 2024, and co-pending application titled “In-Memory Deep Neural Network Device Using Spin Orbit Torque (SOT) With Multi-State Weight,” U.S. application Ser. No. 18/954,415, filed Nov. 20, 2024, the disclosures of which are hereby incorporated by reference. As another example, they can be used in magnetic sensing applications such as those disclosed in co-pending application titled “Magnetic Sensor Half-Bridge Based on Inverse Spin Hall Effect with Reduced Thermal Drift,” U.S. application Ser. No. 18/545,847, filed Dec. 19, 2023, and co-pending application titled “Sensor based on Direct Spin Hall Effect,” U.S. application Ser. No. 18/666,543, filed May 16, 2024, the disclosures of which are hereby incorporated by reference.

Therefore, by utilizing one or more texture layers in a buffer layer, each texture layer comprising a material selected from the group consisting of: Ta, W, Mo, Nb, ScN, TiO₂, RuO₂, VO₂, SnO₂, ZrO, ZrN, HfN, TaN, ZrC, HfC, WZrC, and combinations thereof, a TI or TSM layer comprising YPtBi is able to grow having a (100) orientation or a (110) orientation, or a BiSb layer is able to grow having a (012) orientation, to match the orientation of the interlayer and FM layer. Because the TI or TSM layer has an orientation that matches the orientation of the interlayer and the FM layer, the SOT device can efficiently generate a fully spin-polarized current with a (100) or (110) orientation.

In one embodiment, a spin-orbit torque (SOT) device comprises a seed layer, a (100) texture layer disposed on the seed layer, a first (100) barrier layer disposed on the (100) texture layer, a (100) ferromagnetic (FM) layer disposed over the first (100) barrier layer, a topological insulator (TI) or topological semi-metal (TSM) layer disposed over the first (100) barrier layer, the TI or TSM layer comprising YPtBi in a (100) orientation or BiSb in a (012) orientation, and a second (100) barrier layer disposed between the (100) FM layer and the TI or TSM layer.

The (100) texture layer comprises: X-AI, where X is one or more of Co, Ni, Ru, Rh, and Ir; Cr or CrX alloys, where X is one or more of Mo, Mn, Ti, Ru, and W; RuAl; or W-X, or Ta—X alloys with MgO and TiO, where X is one or more of Ta, Hf, W, V, Ti, Nb and Mo. The first (100) barrier layer and the second (100) barrier layer each individually comprises a material selected from the group consisting of: RuHf; Zr—X alloys, where X is one or more of Co, Cu, Ru, and Rh; Ti—Y alloys, where Y is one or more of Au, Ru, and Rh; B2 ternary A (BxC1-x) alloys; B2 binary alloys; CoZrX, where X is one or more of Ti, Fe, Ni, Nb, and Mo; two or more elements selected from the group consisting of: Ta, Hf, W, Ir, Pt, Y, Zr, Nb, Mo, Mg, Sc, Ti, V, Cr, Fe, Co, Ni, Cu, Ru, Rh, and Ag; oxides of Ti, Mg, Ni, Zn; Zr; X-N or X-C composites, where X is one or more of Sc, Ti, V, Cr, Zr, Nb, Ta, Hf, and W; or MO₂ materials, where M is one or more of Ti, Cr, Ru, Rh, Sn, Sb, Ir, CrNb, CrV, and WV. The (100) texture layer, the first (100) barrier layer, and the second (100) barrier layer are epitaxial. The FM layer is disposed between the first (100) barrier layer and the second (100) barrier layer. The TI or TSM layer is disposed between the first (100) barrier layer and the second (100) barrier layer. The TI or TSM layer comprises YPtBi. A magnetic recording head comprises the SOT device. A magnetic recording device comprises the magnetic recording head. A magneto-resistive memory comprises the SOT device.

In another embodiment, a spin-orbit torque (SOT) device comprises a seed layer, a (110) texture layer disposed on the seed layer, a first (110) barrier layer disposed on the (110) texture layer, a (110) ferromagnetic (FM) layer disposed over the first (110) barrier layer, a topological semi-metal (TSM) layer disposed over the first (110) barrier layer, the TSM layer comprising YPtBi in a (110) orientation, and a second (110) barrier layer disposed between the (110) FM layer and the TSM layer.

The (110) texture layer comprises a material selected from the group consisting of: NiFeW, Ru, NiFeTa, CoFeTa, NiFeGe, or CrX alloys, where X is one or more of V, Ti, Ni, Co, Fe, Nb, Mo, Ta, and W, Ta, W, Mo, Nb, V, WTi, CrMo, RhAl, IrAl, and NiAl. The (110) texture layer, the first (110) barrier layer, and the second (110) barrier layer are epitaxial. The first (110) barrier layer and the second (110) barrier layer each individually comprises a material selected from the group consisting of: RuHf, Zr—X alloys, where X is one or more of Co, Cu, Ru, and Rh, Ti—Y alloys, where Y is one or more of Au, Ru, and Rh, a B2 ternary A (BxC1-x) alloy, CoZrX, where X is one or more of Ti, Fe, Ni, Nb, and Mo, two or more elements selected from the group consisting of: Ta, Hf, W, Ir, Pt, Y, Zr, Nb, Mo, Mg, Sc, Ti, V, Cr, Fe, Co, Ni, Cu, Ru, Rh, and Ag, oxides of Ti, Mg, Ni, Zn, or Zr, X-N or X-C composites, where X is one or more of Sc, Ti, V, Cr, Zr, Nb, Ta, Hf, and W, or MO₂ materials, where M is one or more of Os, Ir, Ru, Rh, and Pd. The FM layer is disposed between the first (100) barrier layer and the second (100) barrier layer. The TI or TSM layer comprises YPtBi. A magnetic recording head comprises the SOT device. A magnetic recording device comprises the magnetic recording head. A magneto-resistive memory comprises the SOT device.

In yet another embodiment, a spin-orbit torque (SOT) device comprises a seed layer, a (100) texture layer disposed on the seed layer, a first (100) barrier layer disposed on the (100) texture layer, a (100) ferromagnetic (FM) layer disposed over the first (100) barrier layer, a topological semi-metal (TSM) layer disposed over the first (100) barrier layer, the TSM layer comprising YPtBi in a (100) orientation, and a second (100) barrier layer disposed between the (100) FM layer and the TSM layer.

The (100) texture layer comprises: X-AI, where X is one or more of Co, Ni, Ru, Rh, and Ir; Cr or CrX alloys, where X is one or more of Mo, Mn, Ti, Ru, and W; RuAl; or W-X, or Ta—X alloys with MgO and TiO, where X is one or more of Ta, Hf, W, V, Ti, Nb and Mo. The first (100) barrier layer and the second (100) barrier layer each individually comprises a material selected from the group consisting of: RuHf; Zr—X alloys, where X is one or more of Co, Cu, Ru, and Rh; Ti—Y alloys, where Y is one or more of Au, Ru, and Rh; B2 ternary A (BxC1-x) alloys; CoZrX, where X is one or more of Ti, Fe, Ni, Nb, and Mo; two or more elements selected from the group consisting of: Ta, Hf, W, Ir, Pt, Y, Zr, Nb, Mo, Mg, Sc, Ti, V, Cr, Fe, Co, Ni, Cu, Ru, Rh, and Ag; oxides of Ti, Mg, Ni, Zn, or Zr; X-N or X-C composites, where X is one or more of Sc, Ti, V, Cr, Zr, Nb, Ta, Hf, and W; or MO₂ materials, where M is one or more of Ti, Cr, Ru, Rh, Sn, Sb, Ir, CrNb, CrV, and WV. The (100) texture layer, the first (100) barrier layer, and the second (100) barrier layer are epitaxial. The TI or TSM layer is disposed between the first (100) barrier layer and the second (100) barrier layer. The TI or TSM layer comprises YPtBi. A magnetic recording head comprises the SOT device. A magnetic recording device comprises the magnetic recording head. A magneto-resistive memory comprises the SOT device.

While the foregoing is directed to embodiments of the present disclosure, other and further embodiments of the disclosure may be devised without departing from the basic scope thereof, and the scope thereof is determined by the claims that follow.

What is claimed is:

1. A spin-orbit torque (SOT) device, comprising:
a seed layer;
a (100) texture layer disposed on the seed layer;
a first (100) barrier layer disposed on the (100) texture layer;
a (100) ferromagnetic (FM) layer disposed over the first (100) barrier layer;
a topological insulator (TI) or topological semi-metal (TSM) layer disposed over the first (100) barrier layer, the TI or TSM layer comprising YPtBi in a (100) orientation or BiSb in a (012) orientation; and
a second (100) barrier layer disposed between the (100) FM layer and the TI or TSM layer.

2. The SOT device of claim 1, wherein the (100) texture layer comprises:
X—Al, where X is one or more of Co, Ni, Ru, Rh, and Ir;
Cr or CrX alloys, where X is one or more of Mo, Mn, Ti, Ru, and W; or
RuAl, W—X, or Ta—X alloys with MgO and TiO, where X is one or more of Ta, Hf, W, V, Ti, Nb and Mo.

3. The SOT device of claim 1, wherein the first (100) barrier layer and the second (100) barrier layer each individually comprises a material selected from the group consisting of:
RuHf;
Zr—X alloys, where X is one or more of Co, Cu, Ru, and Rh;
Ti—Y alloys, where Y is one or more of Au, Ru, and Rh;
B2 ternary A (BxC1-x) alloys;
B2 binary alloys;
CoZrX, where X is one or more of Ti, Fe, Ni, Nb, and Mo;
two or more elements selected from the group consisting of: Ta, Hf, W, Ir, Pt, Y, Zr, Nb, Mo, Mg, Sc, Ti, V, Cr, Fe, Co, Ni, Cu, Ru, Rh, and Ag;
oxides of Ti, Mg, Ni, Zn, or Zr;
X-N or X-C composites, where X is one or more of Sc, Ti, V, Cr, Zr, Nb, Ta, Hf, and W; and
MO₂ materials, where M is one or more of Ti, Cr, Ru, Rh, Sn, Sb, Ir, CrNb, CrV, and WV.

4. The SOT device of claim 1, wherein the (100) texture layer, the first (100) barrier layer, and the second (100) barrier layer are epitaxial.

5. The SOT device of claim 1, wherein the FM layer is disposed between the first (100) barrier layer and the second (100) barrier layer.

6. The SOT device of claim 1, wherein the TI or TSM layer is disposed between the first (100) barrier layer and the second (100) barrier layer.

7. The SOT device of claim 1, wherein the TI or TSM layer comprises YPtBi.

8. A magnetic recording head comprising the SOT device of claim 1.

9. A magnetic recording device comprising the magnetic recording head of claim 8.

10. A magneto-resistive memory comprising the SOT device of claim 1.

11. A spin-orbit torque (SOT) device, comprising:
a seed layer;
a (110) texture layer disposed on the seed layer;
a first (110) barrier layer disposed on the (110) texture layer;
a (110) ferromagnetic (FM) layer disposed over the first (110) barrier layer;
a topological semi-metal (TSM) layer disposed over the first (110) barrier layer, the TSM layer comprising YPtBi in a (110) orientation; and
a second (110) barrier layer disposed between the (110) FM layer and the TSM layer.

12. The SOT device of claim 11, wherein the (110) texture layer comprises a material selected from the group consisting of: NiFeW, NiFeTa, CoFeTa, NiFeGe, Ru, CrX alloys, where X is one or more of V, Ti, Ni, Co, Fe, Nb, Mo, Ta, and W, Ta, W, Mo, Nb, V, WTi, CrMo, RhAl, IrAl, and NiAl.

13. The SOT device of claim 11, wherein the (110) texture layer, the first (110) barrier layer, and the second (110) barrier layer are epitaxial.

14. The SOT device of claim 11, wherein the first (110) barrier layer and the second (110) barrier layer each individually comprises a material selected from the group consisting of:
RuHf;
Zr—X alloys, where X is one or more of Co, Cu, Ru, and Rh;
Ti—Y alloys, where Y is one or more of Au, Ru, and Rh;
B2 ternary A (BxC1-x) alloys;
CoZrX, where X is one or more of Ti, Fe, Ni, Nb, and Mo;
two or more elements selected from the group consisting of: Ta, Hf, W, Ir, Pt, Y, Zr, Nb, Mo, Mg, Sc, Ti, V, Cr, Fe, Co, Ni, Cu, Ru, Rh, and Ag;
oxides of Ti, Mg, Ni, Zn, or Zr;
X-N or X-C composites, where X is one or more of Sc, Ti, V, Cr, Zr, Nb, Ta, Hf, and W; and
MO₂ materials, where M is one or more of Os, Ir, Ru, Rh, and Pd.

15. The SOT device of claim 11, wherein the FM layer is disposed between the first (100) barrier layer and the second (100) barrier layer.

16. The SOT device of claim 11, wherein the TI or TSM layer comprises YPtBi.

17. A magnetic recording head comprising the SOT device of claim 11.

18. A magnetic recording device comprising the magnetic recording head of claim 17.

19. A magneto-resistive memory comprising the SOT device of claim 11.

20. A spin-orbit torque (SOT) device, comprising:
a seed layer;
a (100) texture layer disposed on the seed layer;
a first (100) barrier layer disposed on the (100) texture layer;
a (100) ferromagnetic (FM) layer disposed over the first (100) barrier layer;
a topological semi-metal (TSM) layer disposed over the first (100) barrier layer, the TSM layer comprising YPtBi in a (100) orientation; and
a second (100) barrier layer disposed between the (100) FM layer and the TSM layer.

21. The SOT device of claim 20, wherein the (100) texture layer, the first (100) barrier layer, and the second (100) barrier layer are epitaxial.

22. The SOT device of claim 20, wherein the (100) texture layer comprises:
X—Al, where X is one or more of Co, Ni, Ru, Rh, and Ir;
Cr or CrX alloys, where X is one or more of Mo, Mn, Ti, Ru, and W;
RuAl; or
W—X or Ta—X alloys with MgO and TiO, where X is one or more of Ta, Hf, W, V, Ti, Nb and Mo.

23. The SOT device of claim 20, wherein the first (100) barrier layer and the second (100) barrier layer each individually comprises a material selected from the group consisting of:
RuHf;
Zr—X alloys, where X is one or more of Co, Cu, Ru, and Rh;
Ti—Y alloys, where Y is one or more of Au, Ru, and Rh;
B2 ternary A (BxC1-x) alloys;
CoZrX, where X is one or more of Ti, Fe, Ni, Nb, and Mo;
two or more elements selected from the group consisting of: Ta, Hf, W, Ir, Pt, Y, Zr, Nb, Mo, Mg, Sc, Ti, V, Cr, Fe, Co, Ni, Cu, Ru, Rh, and Ag;
oxides of Ti, Mg, Ni, Zn, or Zr;
X-N or X-C composites, where X is one or more of Sc, Ti, V, Cr, Zr, Nb, Ta, Hf, and W; or
MO₂ materials, where M is one or more of Ti, Cr, Ru, Rh, Sn, Sb, Ir, CrNb, CrV, and WV.

24. The SOT device of claim 20, wherein the TI or TSM layer is disposed between the first (100) barrier layer and the second (100) barrier layer.

25. The SOT device of claim 20, wherein the TI or TSM layer comprises YPtBi.

26. A magnetic recording head comprising the SOT device of claim 20.

27. A magnetic recording device comprising the magnetic recording head of claim 26.

28. A magneto-resistive memory comprising the SOT device of claim 20.
